(19) United States
(12) Patent Application Publication
(10) Pub. No.: US 2009/0316424 A1
(43) Pub. Date: Dec. 24, 2009

(54) Housing for an Operating Device in a Discharge Lamp

(76) Inventors: Stefan Dietz, Otterfing (DE); Lars Kolbe, Glonn (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 12/522,679

(22) PCT Filed: Dec. 19, 2007
(86) PCT No.: PCT/EP2007/064174

§ 371 Date: Jul. 9, 2009

(30) Foreign Application Priority Data
Jan. 9, 2007 (DE) 10 2007 001 392.4

(51) Int. Cl. F21V 15/00; B60Q 1/00; H05K 9/00

(52) U.S. Cl. 362/546; 362/362; 361/818

(57) ABSTRACT

A housing for an operating device (1) of a discharge lamp (5), wherein the housing (2) is adapted to electromagnetically shield the components (1) arranged in the housing (2), and at least regions of the housing, on the outer side, have a protective layer (21) of an electrically conductive and corrosion-resistant material.

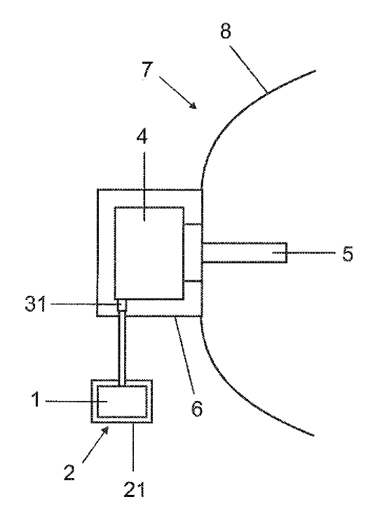

### TECHNICAL FIELD

The invention relates to a housing for an operating device of a discharge lamp.

### PRIOR ART

WO 2005/008125 A1 has disclosed a headlamp of a vehicle, which has a high-pressure discharge lamp. The high-pressure discharge lamp comprises a base in which a starting apparatus is fitted. The base is surrounded by a housing, which acts as an electrically conductive shield for electromagnetic radiation. This shield comprises at least a nonferrous heavy metal or an alloy of at least one nonferrous heavy metal. An external operating device, which is connected to the lamp via a feed line cable, is provided for operating the high-pressure discharge lamp. This feed line cable comprises a plug, whose housing is connected to the housing of the base of the high-pressure discharge lamp. The housing of the plug can be made from the same metal as the housing of the base of the high-pressure discharge lamp or from a metal which has a similar electronegativity as the metal of the housing of the base in order to reduce the risk of electrochemical or galvanic corrosion of the plug-type connection.

Furthermore, it is known that the housings of such external operating devices or electronic control gear can corrode primarily when used in the automotive sector up to the degree of pitting. A coating with conventional corrosion-inhibiting materials, such as paints, is not possible if the housing is intended to be used at the same time as an EMC shield. Since such a paint is electrically insulating, the connection to ground of the printed circuit board would be interrupted. In the case of known housings of such external operating devices, the housing parts are therefore virtually left blank and it is accepted that corrosion will take place. If appropriate, the wall thicknesses of the housing are increased.

### DESCRIPTION OF THE INVENTION

The object of the present invention is to provide a housing for an operating device of a discharge lamp in which a high degree of functionality can be ensured and damage or destruction as a result of environmental influences can at least be reduced.

This object is achieved by a housing having the features of patent claim 1.

A housing according to the invention for an operating device of a discharge lamp is designed to electromagnetically shield the components arranged in the housing. Furthermore, a protective layer comprising an electrically conductive and corrosion-resistant material is formed on at least regions of the outer side of the housing. The housing can therefore at the same time be used for EMC shielding and for corrosion protection owing to influences of environmental conditions. As a result of the electrically conductive design, the connection to ground of a printed circuit board can be ensured.

Preferably, the protective layer is formed by a green chrome plating. As a result, relatively simple and low-complexity manufacture can be ensured. Furthermore, the selection of a so-called green chrome plating can provide a Cr₆-free protective layer, as a result of which increased environmental protection aspects can furthermore also be taken into consideration.

Preferably, the housing has a basic body made from cast magnesium on which the protective layer is formed.

The protective layer preferably comprises chromium trioxide as material constituents. Precisely this constituent allows for particularly reliable protection against corrosive media from the environment. The electrical conductivity of the layer is also provided and EMC shielding ensured.

Preferably, the protective layer is designed to protect the housing from corrosive media in the environment of the operating device. The intention is therefore not to provide protection against electrochemical galvanic corrosion, as is proposed in the prior art for the housing of the lamp base, but from corrosive media, such as acids or salts, as may be the case when using the operating device in a vehicle, for example.

Preferably, the operating device is arranged externally with respect to the discharge lamp and is connected to the discharge lamp by a feed line. Precisely such externally arranged operating devices are subject to high loads in terms of environmental influences. In particular when used in vehicles, the housings are subjected to a high degree of wear as a result of corrosive media.

Preferably, the operating device is arranged in a vehicle and is designed to operate a discharge lamp of a headlamp of the vehicle.

It can also be provided that a housing of a base of the discharge lamp itself is formed with such a protective layer.

### BRIEF DESCRIPTION OF THE DRAWING(S)

An exemplary embodiment of the invention will be explained in more detail below with reference to a schematic drawing, which shows an arrangement, which comprises an operating device with a housing according to the invention.

### PREFERRED EMBODIMENT OF THE INVENTION

The single FIGURE shows an electronic control gear or an operating device 1 with a housing 2. The operating device 1 is arranged in an engine compartment of a vehicle. The housing 2 is in the form of a cast magnesium housing and is designed to electromagnetically shield the components arranged in the housing. A protective layer 21 comprising an electrically conductive and corrosion-resistant material is formed on the outer side of the housing 2. This protective layer 21 is formed by green chrome plating.

The protective layer 21 is designed to protect the housing 2 from corrosive media in the environment of the operating device 1, such as salt fog, acids or the like, for example as can generally occur in the case of such a use location of an operating device 1 in the vehicle.

The operating device 1 is electrically connected to a housing 4 for a base (not illustrated) of a discharge lamp 5 via a feed line 3 via a plug 31. A starting apparatus for the discharge lamp 5 is arranged in the base (not illustrated). The base and the housing 4 of the base are arranged in a receptacle 6 of a headlamp 7. The headlamp 7 furthermore comprises a reflector 8.

By applying the protective layer 21 to the outer side of the housing 2, both the EMC connection of the housing 2 and the corrosion resistance with respect to corrosive media in the environment of the operating device 1 can be realized.

1. A housing for an operating device of a discharge lamp, wherein the housing is adapted to electromagnetically shield the components arranged in the housing, and at least regions of the housing, on the outer side, have a protective layer of an electrically conductive and corrosion-resistant material.

2. The housing as claimed in claim 1, wherein the protective layer is formed by a green chrome plating.

3. The housing as claimed in claim 1, wherein the housing has a basic body made from cast magnesium on which the protective layer is formed.

4. The housing as claimed in claim 1, wherein the protective layer comprises at least a proportion of chromium trioxide.

5. The housing as claimed in claim 1, wherein the protective layer is adapted to protect the housing from corrosive media in the environment of the operating device.

6. The housing as claimed in claim 1, wherein the operating device is arranged externally with respect to the discharge lamp and is connected to the discharge lamp by a feed line.

7. The housing as claimed in claim 1, wherein the operating device is arranged in a vehicle and is adapted to operate a discharge lamp of a headlamp of the vehicle.

8. An operating device of a lamp with a housing as claimed in claim 1.
